(19) United States
(12) Patent Application Publication
(10) Pub. No.: US 2016/0363673 A1
(43) Pub. Date: Dec. 15, 2016

(54) METHOD OF FABRICATING INTEGRATED DIGITAL X-RAY IMAGE SENSOR, AND INTEGRATED DIGITAL X-RAY IMAGE SENSOR USING THE SAME

(71) Applicant: Kookmin University Industry Academy Cooperation Foundation, Seoul (KR)

(72) Inventor: Dong Hwan AHN, Yongin-si (KR)

(21) Appl. No.: 14/804,562

(22) Filed: Jul. 21, 2015

(30) Foreign Application Priority Data
Jun. 9, 2015 (KR) 10-2015-0081095

(51) Int. Cl. G01T 1/20; H01L 27/146

(52) U.S. Cl. CPC G01T 1/2018; H01L 27/14663; H01L 27/14618; H01L 27/14685; H01L 27/14636

(57) ABSTRACT

Provided are a method of fabricating an integrated digital X-ray image sensor, the method including forming a plurality of photodiode units in at least parts of a substrate having a first surface and a second surface, forming a mold on the first surface to correspond to the photodiode units, forming a microstructure having a convex part and concave parts by etching at least parts of the mold by a predetermined depth, and forming a scintillator capable of converting X-rays to a wavelength band detectable by the photodiode units, in the concave parts of the microstructure, or including forming a plurality of photodiode units in at least parts of a substrate having a first surface and a second surface, forming a microstructure having a convex part and concave parts by etching at least parts of the second surface by a predetermined depth to correspond to the photodiode units, and forming a scintillator capable of converting X-rays to a wavelength band detectable by the photodiode units, in the concave parts of the microstructure, and an integrated digital X-ray image sensor using the same.

### CROSS-REFERENCE TO RELATED PATENT APPLICATION

This application claims the benefit of Korean Patent Application No. 10-2015-0081095, filed on Jun. 9, 2015, in the Korean Intellectual Property Office, the disclosure of which is incorporated herein in its entirety by reference.

### BACKGROUND

1. Field

The present invention relates to a method of fabricating an X-ray image sensor, and an X-ray image sensor using the same and, more particularly, to a method of fabricating a digital X-ray image sensor, and a digital X-ray image sensor using the same.

2. Description of the Related Art

A conventional X-ray detection method uses film or magnetic tape. However, the film achieves an excellent image resolution but requires a considerably long time for development or image search, is expensive, and causes environmental pollution. As such, a replacement thereof is demanded. An example thereof is a digital X-ray sensor.

In general, an X-ray has a high transmittance and thus is transmitted through a subject but not 100%. Furthermore, the X-ray is partially transmitted and partially absorbed depending on the density of a reaction material. The transmitted X-ray has an intensity different from that before transmitting through the subject, and is detected by a digital semiconductor sensor.

The digital X-ray detection scheme is divided into a direct detection scheme for reading electron-hole pairs generated by directly reacting with an X-ray, and an indirect detection scheme for converting an X-ray into light through a scintillator and then detecting and reading the light. In general, if an X-ray image is obtained using the indirect detection scheme, a scintillator and a plurality of photodiodes are used and light is scattered in every direction inside the scintillator when an X-ray is projected onto the scintillator, thereby reducing a spatial resolution of the photodiodes. In addition, a bonding method of the scintillator and the photodiodes requires high process costs and a long process time.

### SUMMARY

The present invention provides a method of fabricating a digital X-ray image sensor capable of increasing the sensitivity of a close-up image without attaching an optical module, and a digital X-ray image sensor using the same. However, the scope of the present invention is not limited thereto.

According to an aspect of the present invention, there is provided a method of fabricating an integrated digital X-ray image sensor, the method including forming a plurality of photodiode units in at least parts of a substrate having a first surface and a second surface, forming a mold on the first surface to correspond to the plurality of photodiode units, forming a microstructure having a convex part and concave parts by etching at least parts of the mold by a predetermined depth, and forming a scintillator capable of converting X-rays to a wavelength band detectable by the photodiode units, in the concave parts of the microstructure.

According to another aspect of the present invention, there is provided a method of fabricating an integrated digital X-ray image sensor, the method including forming a plurality of photodiode units in at least parts of a substrate having a first surface and a second surface, forming a microstructure having a convex part and concave parts by etching at least parts of the second surface by a predetermined depth to correspond to the plurality of photodiode units, and forming a scintillator capable of converting X-rays to a wavelength band detectable by the photodiode units, in the concave parts of the microstructure.

The method may further include forming a wiring layer on the first surface after the photodiode units are formed.

The forming of the microstructure may include forming a plurality of recesses by selectively etching at least parts of the mold or the second surface by a predetermined depth using photolithography.

The convex part of the microstructure may serve as a barrier capable of preventing scattering of the X-rays incident on the scintillator.

The X-rays may be detectable by the photodiode units through the substrate by processing at least parts of the second surface by a predetermined depth using a chemical mechanical polishing process or an etch-back process.

According to another aspect of the present invention, there is provided an integrated digital X-ray image sensor including a plurality of photodiode units provided in at least parts of a substrate having a first surface and a second surface, a microstructure having a convex part and concave parts formed by etching at least parts of a mold provided on the first surface by a predetermined depth to correspond to the plurality of photodiode units, and a scintillator capable of converting X-rays to a wavelength band detectable by the photodiode units, and provided in the concave parts of the microstructure.

According to another aspect of the present invention, there is provided an integrated digital X-ray image sensor including a plurality of photodiode units provided in at least parts of a substrate having a first surface and a second surface, a microstructure having a convex part and concave parts formed by etching at least parts of the second surface by a predetermined depth to correspond to the plurality of photodiode units, and a scintillator capable of converting X-rays to a wavelength band detectable by the photodiode units, and provided in the concave parts of the microstructure.

The integrated digital X-ray image sensor may further include a wiring layer provided on the first surface to control the photodiode units.

The concave parts of the microstructure may include a number of recesses at least corresponding to the photodiode units.

The concave parts of the microstructure corresponding to the photodiode units may be aligned with and provided on the photodiode units.

The concave parts of the microstructure may have a size equal to a size of the photodiode units.

The concave parts of the microstructure may extend perpendicularly to the substrate in such a manner that light is focused onto one of the photodiode units which is closest to a light source.

The scintillator may include a plurality of phosphor particles or powders randomly spaced apart from each other.

The scintillator may include a continuous material capable of uniformly filling the concave parts, a thin film having a form of columnar growth, or a material formed of particles or powers bonded to each other.

### BRIEF DESCRIPTION OF THE DRAWINGS

The above and other features and advantages of the present invention will become more apparent by describing in detail embodiments thereof with reference to the attached drawings in which:

FIG. 1 is a flowchart of a method of fabricating an integrated digital X-ray image sensor, according to an embodiment of the present invention;

FIG. 2 is a flowchart of a method of fabricating an integrated digital X-ray image sensor, according to another embodiment of the present invention;

FIG. 3 is a plan view of an integrated digital X-ray image sensor according to an embodiment of the present invention;

FIG. 4 is a cross-sectional view of the integrated digital X-ray image sensor 1000 of FIG. 3;

FIG. 5A to FIG. 5F are cross-sectional views for describing a method of fabricating an integrated digital X-ray image sensor, according to an embodiment of the present invention; and

FIGS. 6A to 6D are cross-sectional views for describing a method of fabricating an integrated digital X-ray image sensor, according to another embodiment of the present invention.

### DETAILED DESCRIPTION

Reference will now be made in detail to embodiments, examples of which are illustrated in the accompanying drawings. However, embodiments are not limited to the embodiments illustrated hereinafter, and the embodiments herein are rather introduced to provide easy and complete understanding of the scope and spirit of embodiments. In the drawings, the sizes of elements can be exaggerated or reduced for clarity.

It will be understood that when an element, such as a layer, a region, or a substrate, is referred to as being “on,” “connected to”, “stacked on” or “coupled to” another element, it may be directly on, connected to, stacked on or coupled to the other element or intervening elements may be present. In contrast, when an element is referred to as being “directly on,” “directly connected to”, “directly stacked on” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of embodiments.

Spatially relative terms, such as “above,” “upper,” “beneath,” “below,” “lower,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “above” may encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-sectional illustrations that are schematic illustrations of embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but may be to include deviations in shapes that result, for example, from manufacturing.

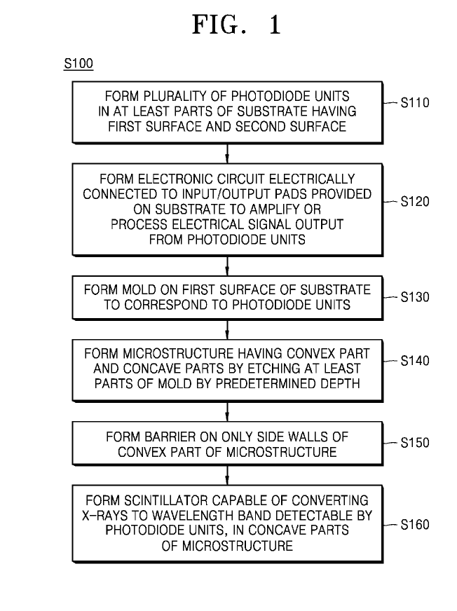

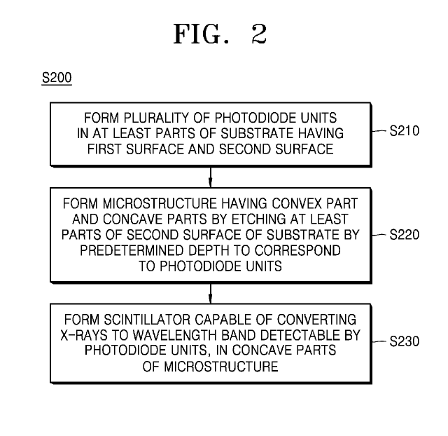

FIG. 1 is a flowchart of a method S100 of fabricating an integrated digital X-ray image sensor, according to an embodiment of the present invention, and FIG. 2 is a flowchart of a method S200 of fabricating an integrated digital X-ray image sensor, according to another embodiment of the present invention.

Referring to FIG. 1, the method S100 of fabricating the integrated digital X-ray image sensor, according to an embodiment of the present invention may include forming a plurality of photodiode units in at least parts of a substrate having a first surface and a second surface (S110), forming an electronic circuit electrically connected to input/output pads provided on the substrate to amplify or process an electrical signal output from the photodiode units (S120), forming a mold on the first surface to correspond to the photodiode units (S130), forming a microstructure having a convex part and concave parts by etching at least parts of the mold by a predetermined depth (S140), forming a barrier on only side walls of the convex part of the microstructure (S150), and forming a scintillator capable of converting X-rays to a wavelength band detectable by the photodiode units, in the concave parts of the microstructure (S160).

According to the method S100 of fabricating the integrated digital X-ray image sensor, a material of the scintillator is divided into pieces corresponding to individual image sensing pixels to prevent scattering of light emitted from the scintillator and to prevent a dull, e.g., blurred, image due to scattered light. The scintillator is designed in such a manner that the divided pieces thereof spatially correspond one-to-one to pixel units of a sensor array.

In addition, an optical structure is designed to prevent image quality degradation which is caused when light emitted from each divided pixel of the scintillator proceeds toward and is detected from other adjacent pixels, and the integrated digital X-ray image sensor may be implemented by designing a fabricating process of a scintillator structure as a single process, e.g., monolithic integration, to save costs and time of a process of packaging a scintillator material, an image sensor array, and an electronic circuit substrate.

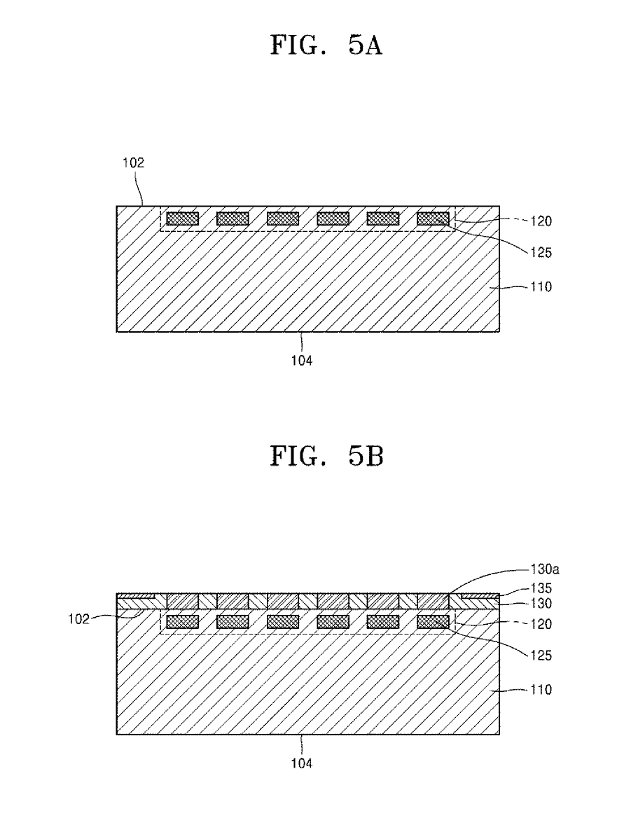

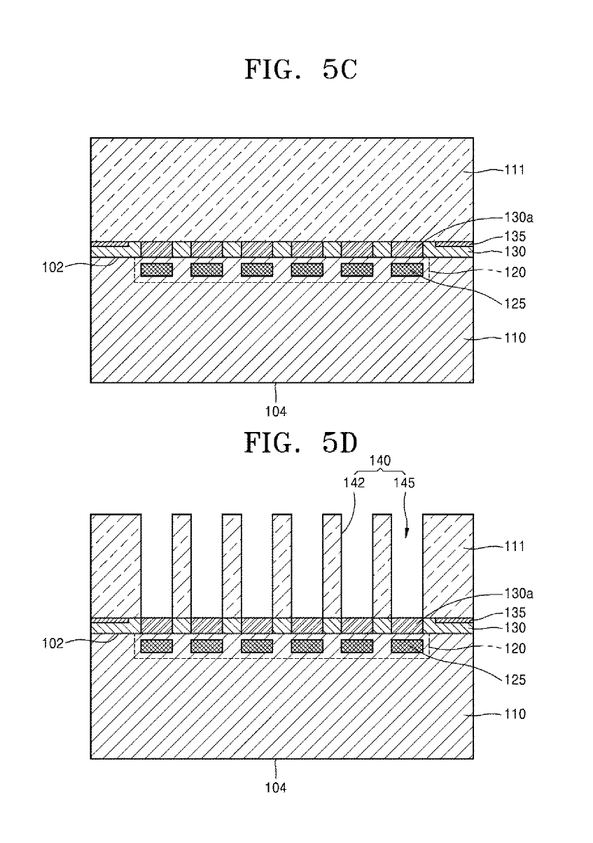

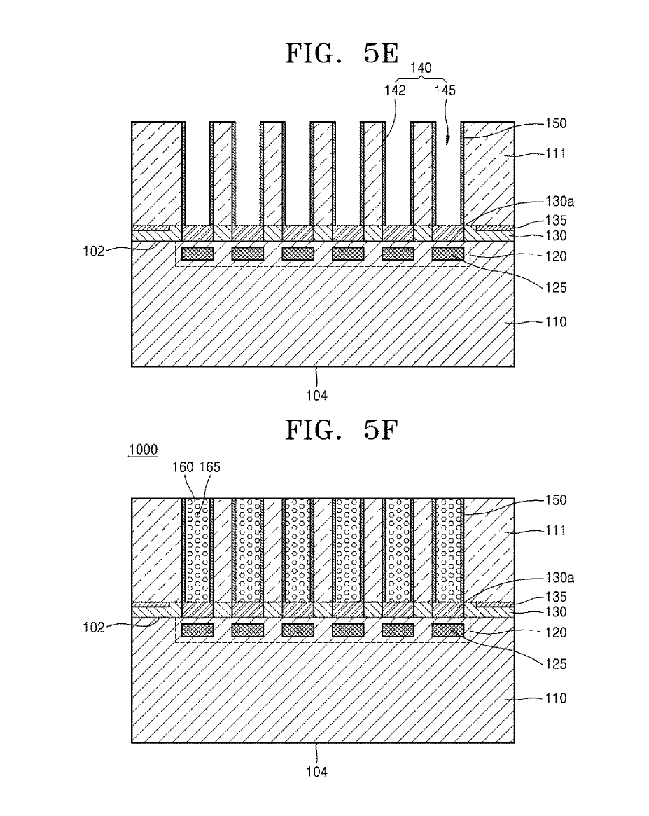

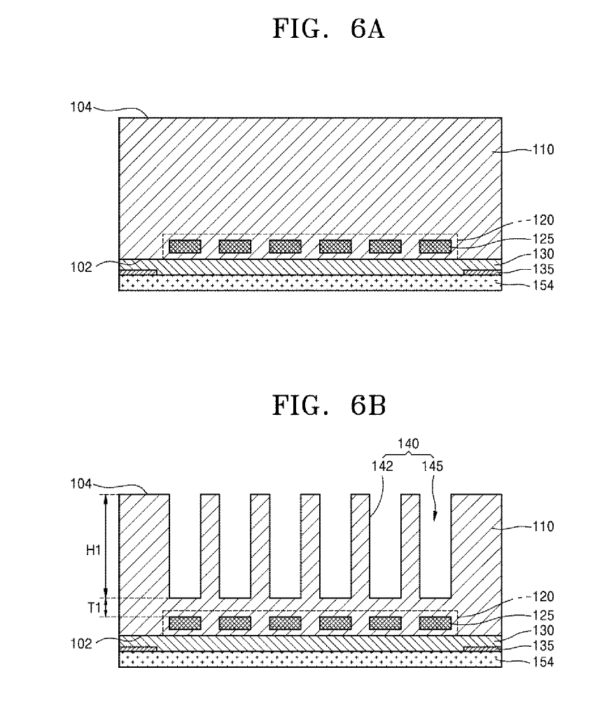

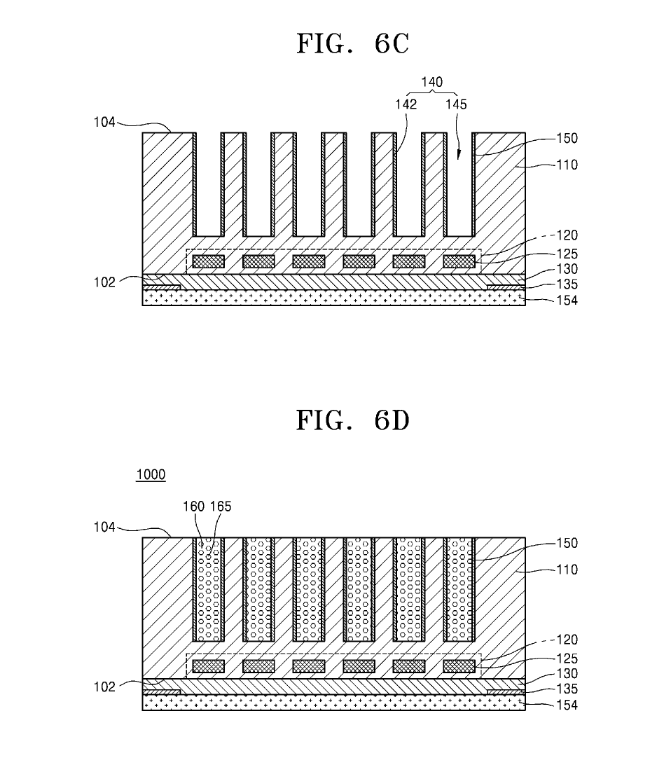

Referring to FIG. 2, the method S200 of fabricating the integrated digital X-ray image sensor, according to another embodiment of the present invention may include forming a plurality of photodiode units in at least parts of a substrate having a first surface and a second surface (S210), forming a microstructure having a convex part and concave parts by etching at least parts of the second surface of the substrate by a predetermined depth to correspond to the photodiode units (S220), and forming a scintillator capable of converting X-rays to a wavelength band detectable by the photodiode units, in the concave parts of the microstructure (S230). Here, detailed descriptions of the above-described methods S100 and S200 of fabricating the integrated digital X-ray image sensor will be given below with reference to FIGS. 5A to 5F, and FIGS. 6A to 6D.

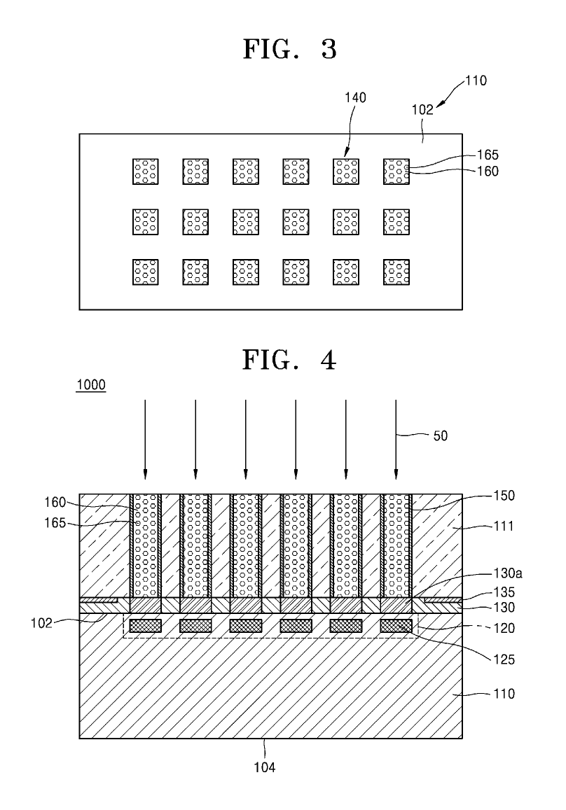

FIG. 3 is a plan view of an integrated digital X-ray image sensor 1000 according to an embodiment of the present invention, and FIG. 4 is a cross-sectional view of the integrated digital X-ray image sensor 1000 of FIG. 3.

Referring to FIGS. 3 and 4, a substrate 110 including a first surface 102 and a second surface 104 may be provided. The first surface 102 may be understood as a front surface of the substrate 110, and the second surface 104 may be understood as a rear surface of the substrate 110. For example, the substrate 110 may include a Group semiconductor, e.g., silicon, germanium, or silicon-germanium, a Group—and Group—compound semiconductor, or an oxide semiconductor.

A sensor array 120 may be provided adjacent the first surface 102 of the substrate 110, i.e., in the substrate 110. The sensor array 120 may include a plurality of photodiode units 125 for converting an optical signal into an electrical signal. The photodiode units 125 may be provided under the first surface 102 by, for example, injecting impurities ions into the first surface 102 of the substrate 110. For example, the sensor array 120 may include a charge coupled device (CCD) or a complementary metal-oxide-semiconductor (CMOS) image sensor.

A wiring layer 130 and light-transmitting layers 130a may be provided on the sensor array 120, i.e., on the first surface 102 of the substrate 110. Input/output pads 135 may be provided on the wiring layer 130. The input/output pads 135 may be used to output the electrical signal of the sensor array 120 to an external device or to receive an electrical signal input from the external device. Although not shown in FIGS. 3 and 4, an electronic circuit may be provided to be electrically connected to the input/output pads 135 and thus may amplify or process the electrical signal output from the photodiode units 125. The electronic circuit may be provided at a side of the substrate 110 not to exert an influence on the photodiode units 125 due to incident light, or may be provided outside the sensor array 120, e.g., on a surface of a mold covering the sensor array 120, depending on the structure of the sensor array 120.

The integrated digital X-ray image sensor 1000 may include a mold 111 including a microstructure 140 having a convex part 142 and concave parts 145 (See FIG. 5D), on the wiring layer 130. The microstructure 140 may include the concave parts 145, i.e. a plurality of recesses, formed from the first surface 102 toward the second surface 104 of the substrate 110. The microstructure 140 may function to guide light from the first surface 102 of the substrate 110 through the concave parts 145 to the sensor array 120, i.e., the photodiode units 125.

The concave parts 145 may be provided on the sensor array 120 to at least partially overlap with the photodiode units 125. The concave parts 145 may be provided to correspond to the photodiode units 125 at least one to one in number and to be aligned with the centers of the photodiode units 125. The microstructure 140 may include the convex part 142 surrounding the concave parts 145.

In this alignment, the size of the concave parts 145 may be greater than the size of the photodiode units 125 to increase the sensitivity of an image signal. Alternatively, the size of the concave parts 145 may be equal to the size of the photodiode units 125 to minimize loss of the image signal outside the photodiode units 125.

According to a modified example of the current embodiment, if a certain level of intensity of an optical signal is ensured, the size of the concave parts 145 may be less than the size of the photodiode units 125. The convex part 142 around the concave parts 145 may prevent scattering of incident light. That is, the convex part 142 of the microstructure 140 may serve as a barrier capable of preventing scattering of X-rays incident on a scintillator 160.

If a commercialized CMOS image sensor (not shown) is used, the above-described microstructure 140 may be provided after removing a microlens array provided on the CMOS image sensor. Here, the microlens array is used to focus incident light onto the sensor, which is the same as the function of the scintillator 160, and thus may be removed. The integrated digital X-ray image sensor 1000 according to the present invention may omit the operation for removing the microlens array, and thus process costs and process times may be reduced. Alternatively, the microlens array may not be removed and a mold having a barrier or convex-concave structure may be directly provided on the microlens array.

The scintillator 160 may include a plurality of phosphor particles or powders 165 which are randomly spaced apart from each other. The scintillator 160 may include a continuous material capable of uniformly filling the above-described concave parts 145, a thin film having a form of columnar growth, or a material formed of fine particles or fine powders bonded to each other. Here, the continuous material capable of uniformly filling the concave parts 145, or the material in which fine particles or powder particles are bonded to each other may be a fluidic material.

A description is now given of the operation of the scintillator 160. Light induced from an X-ray is converted into visible light or light of a wavelength band detectable by the photodiode units 125 by the phosphor particles or powders 165 included in the scintillator 160, and light emitted from the scintillator 160 may be detected by the photodiode units 125 without being scattered around pixels by adding a barrier 150 serving as a mirror on side surfaces of the convex part 142 of the microstructure 140. In this case, compared to a case in which the barrier 150 is not provided, the sensitivity of light may be improved using the barrier 150.

Light 50 emitted from a light source may be incident on the sensor array 120 from the first surface 102 of the substrate 110 through the microstructure 140. In this case, the light 50 emitted from the light source may be incident in a direction perpendicular to the substrate 110, entirely pass through the concave parts 145, and then incident on the photodiode units 125 under the concave parts 145. Accordingly, the light 50 may be incident on the photodiode units 125 with little lost through the microstructure 140. As such, the concave parts 145 may extend perpendicularly to the substrate 110, that is, the convex part 142 and the concave parts 145 may extend perpendicularly to the sensor array 120, in such a manner that the light 50 is focused onto one of the photodiode units 125 which is the closest to the light source.

FIGS. 5A to FIG. 5F are cross-sectional views for describing a method of fabricating an integrated digital X-ray image sensor 1000, according to an embodiment of the present invention.

Initially, referring to FIGS. 5A and 5B, a substrate 110 having a first surface 102 and a second surface 104 may be prepared. A sensor array 120 may be formed under the first surface 102 of the substrate 110. For example, a plurality of photodiode units 125 may be formed by injecting impurities into the first surface 102 of the substrate 110. After the impurities are injected, heat treatment may be performed to activate and spread the impurities.

A wiring layer 130 and light-transmitting layers 130a may be formed on the sensor array 120, i.e., on the first surface 102 of the substrate 110. The wiring layer 130 may include transistors for controlling the sensor array 120, in an insulator, and metal wires (not shown) connected to the transistors. The light-transmitting layers 130a are formed of an insulator capable of transmitting light, which is incident through a scintillator 160 to be described below, to be detected by the photodiode units 125, and may be understood as the above-described insulator in which the metal wires of the wiring layer 130 are formed. The light-transmitting layers 130a may be aligned in such a manner that rays of light correspond to the photodiode units 125 one to one, and thus may form an array. Here, semiconductor fabricating processes for forming the wiring layer 130, the light-transmitting layers 130a, and input/output pads 135 are well known, and thus detailed descriptions thereof are not provided here.

Referring to FIGS. 5C and 5D, a mold 111 may be formed on the wiring layer 130 and the input/output pads 135. Here, the mold 111 is formed of one of a material of the substrate 110, an insulator, and a material capable of reflecting incident light, and is integrated with the substrate 110.

A microstructure 140 may be formed by etching at least parts of the first surface 102 of the substrate 110 by a predetermined depth using photolithography to overlap with the location of the photodiode units 125. A convex part 142 and concave parts 145 of the microstructure 140 may be formed in a direction in which light is incident on the photodiode units 125. In this case, since the photodiode units 125 and the concave parts 145 of the microstructure 140 have the same location and size, an alignment operation may not be performed and thus easy fabricating may be achieved.

The convex part 142 and the concave parts 145 of the microstructure 140 may be formed by depositing a mask pattern, or directly depositing an insulating layer or a material capable of reflecting incident light on only a selected region of the wiring layer 130, without forming the mold 111 on the substrate 110. In this case, processes for depositing and etching the mold 111 may be omitted and thus the number of processes and costs may be reduced. Since the photodiode units 125 and the concave parts 145 of the microstructure 140 have the same location and size, an alignment operation may not be performed.

Referring to FIGS. 5E and 5F, a barrier 150 may be formed in pixels of the microstructure 140 using a thin metal film. The barrier 150 may be deposited on only side walls of the convex part 142 of the microstructure 140 using an electrochemical deposition scheme, a physical vapor deposition scheme, or a chemical vapor deposition scheme. Alternatively, the barrier 150 may be formed on the side walls of the convex part 142 of the microstructure 140 by coating the barrier 150 on the whole surface of the mold 111 and the light-transmitting layers 130a, and then etching only unnecessary parts thereof. Here, the electrochemical deposition scheme, the physical vapor deposition scheme, or the chemical vapor deposition scheme is well known, and a detailed description thereof is not provided here.

The scintillator 160 may be formed in the concave parts 145 surrounded by the barrier 150. The scintillator 160 includes the phosphor particles or powders 165 which are randomly spaced apart from each other in the scintillator 160. By performing a spin coating process, a process of eliminating unnecessary parts after the scintillator 160 is deposited, etc., the scintillator 160 may be formed at low costs and thus the integrated digital X-ray image sensor 1000 may be implemented.

FIGS. 6A to 6D are cross-sectional views for describing a method of fabricating an integrated digital X-ray image sensor 1000, according to another embodiment of the present invention.

Referring to FIGS. 6A and 6B, the integrated digital X-ray image sensor 1000 may be implemented by processing a second surface 104 of a substrate 110, i.e. a rear surface of the substrate 110. Initially, as illustrated in FIGS. 5A and 5B, a sensor array 120 may be formed under a first surface 102 of the substrate 110. For example, a plurality of photodiode units 125 may be formed in the substrate 110.

A wiring layer 130 may be formed on the sensor array 120, and input/output pads 135 may be formed on the wiring layer 130. Here, detailed descriptions of the sensor array 120, the wiring layer 130, and the input/output pads 135 have been given above in relation to FIGS. 5A and 5B, and thus are not provided here. Since light is incident from the rear surface of the substrate 110, the light-transmitting layers 130a described above in relation to FIG. 5B do not need to be formed. However, an insulating layer may be deposited to easily form the wiring layer 130 using metal. If the integrated digital X-ray image sensor 1000 is implemented by processing the second surface 104 of the substrate 110, a very simple sensor structure may be achieved because the light-transmitting layers 130a do not need to be designed, and a large number of economical effects may be achieved because many processes are omittable.

A protective layer 154 may be formed on the wiring layer 130 to cover the input/output pads 135. For example, the protective layer 154 may include detachable plastic tape. If a commercialized CMOS image sensor (not shown) is used as the substrate 110, a microlens array provided on the CMOS image sensor should be removed. However, the microlens array may serve as the above-described protective layer 154 and thus may not be removed.

Subsequently, concave parts 145 may be formed by flipping the substrate 110 and selectively etching the second surface 104 of the substrate 110 using photolithography. For example, a photoresist pattern (not shown) may be formed on the second surface 104 of the substrate 110. Then, the concave parts 145 may be formed by etching the substrate 110 using the photoresist pattern as an etching mask.

The substrate 110 may be etched using reactive ion etching (RIE). According to another embodiment, the concave parts 145 may be formed using laser drilling without forming the photoresist pattern.

If the thickness of the substrate 110 is large, the second surface 104 of the substrate 110 may be flattened using a chemical mechanical polishing process or an etch-back process in such a manner that X-rays are detected by the photodiode units 125 through the substrate 110, or a microstructure 140 having the concave parts 145 and a convex part 142 may be directly formed.

Furthermore, if the microstructure 140 is formed by processing the second surface 104 of the substrate 110, i.e., the rear surface of the substrate 110, a reduction in sensing sensitivity which is caused by interference between adjacent rays of incident light due to the wiring layer 130 may be solved. In addition, since the integrated digital X-ray image sensor 1000 may be implemented using a simple fabricating process without forming the mold 111 of FIG. 5C, process costs may be reduced and the integrated digital X-ray image sensor 1000 may have a high sensitivity.

A thickness T1 of the substrate 110 from bottoms of the concave parts 145 of the microstructure 140 to the photodiode units 125 needs to be appropriately adjusted to allow transmission of light through the substrate 110. That is, considering that light of a small wavelength band cannot easily pass through the substrate 110 if the thickness T1 is large, the thickness T1 needs to be adjusted to be small if the incident light has a small wavelength band.

For example, if the incident light is visible light, the thickness T1 may be set as small as possible to increase the efficiency of transmission of light. Otherwise, if the incident light is infrared light, the thickness T1 may be allowed to a certain value in consideration of a high transmittance of the infrared light. The thickness T1 may be adjusted by adjusting a depth H1 of the concave parts 145 of the microstructure 140.

Referring to FIGS. 6C and 6D, the photoresist pattern may be removed and then a barrier 150 may be formed in pixels of the microstructure 140 using a thin metal film. A scintillator 160 may be formed in the concave parts 145 surrounded by the barrier 150 and thus the integrated digital X-ray image sensor 1000 may be implemented. Here, detailed descriptions of the barrier 150 and the scintillator 160 have been given above in relation to FIGS. 5E 5F, and thus are not provided here.

As described above, if a scintillator absorbs energy of X-rays, converts the same into light of a visible wavelength band, and emits the visible light, a digital X-ray image sensor of an indirect conversion type detects the visible light using a general image sensor. Compared to a direct conversion type, image resolution is reduced a lot.

To solve this problem, the present invention may simplify the structures of a scintillator and an image sensor element to prevent a reduction in image resolution, and may accordingly improve a process of fabricating an integrated digital X-ray image sensor, thereby achieving a high image resolution.

In addition, the integrated digital X-ray image sensor according to the present invention has a structure capable of achieving advantages of low process costs and high-sensitivity and high-quality images in a digital X-ray sensor which is a significant part of a medical imaging device, and is applicable to a computed tomography (CT) scan imaging device as well as a medical X-ray device.

As described above, according to an embodiment of the present invention, a method of fabricating an integrated digital X-ray image sensor having a simple structure and capable of obtaining a high-sensitivity and high-resolution image signal at low costs, and an integrated digital X-ray image sensor using the method may be implemented. However, the scope of the present invention is not limited to the above effect.

While the present invention has been particularly shown and described with reference to embodiments thereof, it will be understood by those of ordinary skill in the art that various changes in form and details may be made therein without departing from the spirit and scope of the present invention as defined by the following claims.

What is claimed is:

1. A method of fabricating an integrated digital X-ray image sensor, the method comprising:
forming a plurality of photodiode units in at least parts of a substrate having a first surface and a second surface;
forming a mold on the first surface to correspond to the plurality of photodiode units;
forming a microstructure having a convex part and concave parts by etching at least parts of the mold by a predetermined depth; and
forming a scintillator capable of converting X-rays to a wavelength band detectable by the photodiode units, in the concave parts of the microstructure.

2. The method of claim 1, further comprising forming a wiring layer on the first surface after the photodiode units are formed.

3. The method of claim 1, wherein the forming of the microstructure comprises forming a plurality of recesses by selectively etching at least parts of the mold or the second surface by a predetermined depth using photolithography.

4. The method of claim 1, wherein the convex part of the microstructure serves as a barrier capable of preventing scattering of the X-rays incident on the scintillator.

5. The method of claim 1, wherein the X-rays are detectable by the photodiode units through the substrate by processing at least parts of the second surface by a predetermined depth using a chemical mechanical polishing process or an etch-back process.

6. A method of fabricating an integrated digital X-ray image sensor, the method comprising:
forming a plurality of photodiode units in at least parts of a substrate having a first surface and a second surface;
forming a microstructure having a convex part and concave parts by etching at least parts of the second surface by a predetermined depth to correspond to the plurality of photodiode units; and
forming a scintillator capable of converting X-rays to a wavelength band detectable by the photodiode units, in the concave parts of the microstructure.

7. The method of claim 6, further comprising forming a wiring layer on the first surface after the photodiode units are formed.

8. The method of claim 6, wherein the forming of the microstructure comprises forming a plurality of recesses by selectively etching at least parts of the mold or the second surface by a predetermined depth using photolithography.

9. The method of claim 6, wherein the convex part of the microstructure serves as a barrier capable of preventing scattering of the X-rays incident on the scintillator.

10. The method of claim 6, wherein the X-rays are detectable by the photodiode units through the substrate by processing at least parts of the second surface by a predetermined depth using a chemical mechanical polishing process or an etch-back process.

11. An integrated digital X-ray image sensor comprising:
a plurality of photodiode units provided in at least parts of a substrate having a first surface and a second surface;
a microstructure having a convex part and concave parts formed by etching at least parts of a mold provided on the first surface by a predetermined depth to correspond to the plurality of photodiode units; and
a scintillator capable of converting X-rays to a wavelength band detectable by the photodiode units, and provided in the concave parts of the microstructure.

12. The integrated digital X-ray image sensor of claim 11, further comprising a wiring layer provided on the first surface to control the photodiode units.

13. The integrated digital X-ray image sensor of claim 11, wherein the concave parts of the microstructure comprise a number of recesses at least corresponding to the photodiode units.

14. The integrated digital X-ray image sensor of claim 11, wherein the concave parts of the microstructure corresponding to the photodiode units are aligned with and provided on the photodiode units.

15. The integrated digital X-ray image sensor of claim 11, wherein the concave parts of the microstructure have a size equal to a size of the photodiode units.

16. The integrated digital X-ray image sensor of claim 11, wherein the concave parts of the microstructure extend perpendicularly to the substrate in such a manner that light is focused onto one of the photodiode units which is closest to a light source.

17. The integrated digital X-ray image sensor of claim 11, wherein the scintillator comprises a plurality of phosphor particles or powders randomly spaced apart from each other.

18. The integrated digital X-ray image sensor of claim 11, wherein the scintillator comprises a continuous material capable of uniformly filling the concave parts, a thin film having a form of columnar growth, or a material formed of particles or powers bonded to each other.
